(19) United States
(12) Patent Application Publication
(10) Pub. No.: US 2026/0163527 A1
(43) Pub. Date: Jun. 11, 2026

(54) ELECTRONIC DEVICE INCLUDING SUPPLY MODULATOR FOR EFFICIENT OUTPUT

(71) Applicant: SAMSUNG ELECTRONICS CO., LTD., Suwon-si (KR)

(72) Inventors: Jaekwang KWON, Suwon-si (KR); Dongki KIM, Suwon-si (KR); Hyeongjin KIM, Suwon-si (KR); Kyeongho YEOM, Suwon-si (KR); Daeyoung LEE, Suwon-si (KR); Heesung LEE, Suwon-si (KR)

(21) Appl. No.: 19/352,282

(22) Filed: Oct. 7, 2025

(30) Foreign Application Priority Data
Dec. 9, 2024 (KR) 10-2024-0181462

(51) Int. Cl. H03F 1/02; H03F 3/24; H04B 1/04

(52) U.S. Cl. CPC H03F 1/0238; H03F 3/245; H04B 1/0475; H03F 2200/451; H04B 2001/0408

(57) ABSTRACT

The present disclosure relates to a 5G communication system or a 6G communication system for supporting higher data rates beyond a 4G communication system such as long term evolution (LTE). A supply modulator in a wireless communication system may include a voltage modulator configured to transmit a first current for voltage switching to a power amplifier, a capacitor configured to maintain a voltage offset, a controller configured to transmit a signal for controlling a voltage across both terminals of the capacitor, and a direct current (DC)/DC converter configured to transmit a second current for supply modulation to the power amplifier.

### CROSS-REFERENCE TO RELATED APPLICATION

This application is based on and claims priority under 35 U.S.C. § 119 to Korean Patent Application No. 10-2024-0181462, filed on Dec. 9, 2024, in the Korean Intellectual Property Office, the disclosure of which is herein incorporated by reference in its entirety.

### BACKGROUND

### 1. Field

The disclosure relates to generally a wireless communication system and, more particularly, to a supply modulator for energy efficiency in a wireless communication system, and an electronic device including the same.

### 2. Description of Related Art

Considering the development of wireless communication from generation to generation, the technologies have been developed mainly for services targeting humans, such as voice calls, multimedia services, and data services. Following the commercialization of 5th generation (5G) communication systems, it is expected that the number of connected devices will exponentially grow. Increasingly, these will be connected to communication networks. Examples of connected things may include vehicles, robots, drones, home appliances, displays, smart sensors connected to various infrastructures, construction machines, and factory equipment. Mobile devices are expected to evolve in various form-factors, such as augmented reality glasses, virtual reality headsets, and hologram devices. In order to provide various services by connecting hundreds of billions of devices and things in the 6th generation (6G) era, there have been ongoing efforts to develop improved 6G communication systems. For these reasons, 6G communication systems are referred to as beyond-5G systems.

6G communication systems, which are expected to be commercialized around 2030, will have a peak data rate of tera (1,000 giga)-level bit per second (bps) and a radio latency less than 100 μsec, and thus will be 50 times as fast as 5G communication systems and have a 1/10 radio latency thereof.

In order to accomplish such a high data rate and an ultra-low latency, it has been considered to implement 6G communication systems in a terahertz (THz) band (for example, 95 gigahertz (GHz) to 3 THz bands). It is expected that, due to severer path loss and atmospheric absorption in the terahertz bands than those in mmWave bands introduced in 5G, technologies capable of securing the signal transmission distance (that is, coverage) will become more crucial. It is necessary to develop, as major technologies for securing the coverage, radio frequency (RF) elements, antennas, novel waveforms having a better coverage than orthogonal frequency division multiplexing (OFDM), beamforming and massive multiple-input multiple-output (MIMO), full dimensional MIMO (FD-MIMO), array antennas, and multiantenna transmission technologies such as large-scale antennas. In addition, there has been ongoing discussion on new technologies for improving the coverage of terahertz-band signals, such as metamaterial-based lenses and antennas, orbital angular momentum (OAM), and reconfigurable intelligent surface (RIS).

Moreover, in order to improve the spectral efficiency and the overall network performances, the following technologies have been developed for 6G communication systems: a full-duplex technology for enabling an uplink transmission and a downlink transmission to simultaneously use the same frequency resource at the same time; a network technology for utilizing satellites, high-altitude platform stations (HAPS), and the like in an integrated manner; an improved network structure for supporting mobile base stations and the like and enabling network operation optimization and automation and the like; a dynamic spectrum sharing technology via collision avoidance based on a prediction of spectrum usage; an use of artificial intelligence (AI) in wireless communication for improvement of overall network operation by utilizing AI from a designing phase for developing 6G and internalizing end-to-end AI support functions; and a next-generation distributed computing technology for overcoming the limit of UE computing ability through reachable super-high-performance communication and computing resources (such as mobile edge computing (MEC), clouds, and the like) over the network. In addition, through designing new protocols to be used in 6G communication systems, developing mechanisms for implementing a hardware-based security environment and safe use of data, and developing technologies for maintaining privacy, attempts to strengthen the connectivity between devices, optimize the network, promote softwarization of network entities, and increase the openness of wireless communications are continuing.

It is expected that research and development of 6G communication systems in hyper-connectivity, including person to machine (P2M) as well as machine to machine (M2M), will allow the next hyper-connected experience. Particularly, it is expected that services such as truly immersive extended reality (XR), high-fidelity mobile hologram, and digital replica could be provided through 6G communication systems. In addition, services such as remote surgery for security and reliability enhancement, industrial automation, and emergency response will be provided through the 6G communication system such that the technologies could be applied in various fields such as industry, medical care, automobiles, and home appliances.

The above information is presented as background information only to assist with an understanding of the disclosure. No determination has been made, and no assertion is made, as to whether any of the above might be applicable as prior art with regard to the disclosure.

### SUMMARY

The disclosure generally relates to a wireless communication system and, more particularly, to a supply modulator for energy saving and efficient output in a wireless communication system, and an electronic device including the same.

Various embodiments of the disclosure are to provide a device and a method capable of effectively providing services in a wireless communication system.

The technical subjects pursued in the disclosure may not be limited to the above-mentioned technical subjects, and other technical subjects which are not mentioned herein may be clearly understood from the following description by those skilled in the art to which the disclosure pertains.

According to various embodiments of the disclosure, a supply modulator in a wireless communication system may include a voltage modulator configured to transmit a first current for voltage switching to a power amplifier, a capacitor configured to maintain a voltage offset, a controller configured to transmit a signal for controlling a voltage across both terminals of the capacitor, and a direct current (DC)/DC converter configured to transmit a second current for supply modulation to the power amplifier.

According to various embodiments of the disclosure, a radio frequency integrated circuit (RFIC) in a wireless communication system may include a plurality of radio frequency (RF) processing chains, wherein each of the plurality of RF processing chains includes a supply modulator and a power amplifier, and the supply modulator includes a voltage modulator configured to transmit a first current for voltage switching to the power amplifier, a capacitor configured to maintain a voltage offset, a controller configured to transmit a signal for controlling a voltage across both terminals of the capacitor, and a direct current (DC)/DC converter configured to transmit a second current for supply modulation to the power amplifier.

The disclosure provides an electronic device capable of effectively providing services in a wireless communication system.

Advantageous effects obtainable from the disclosure may not be limited to the above-mentioned effects, and other effects which are not mentioned herein may be clearly understood from the following description by those skilled in the art to which the disclosure pertains.

Before undertaking the DETAILED DESCRIPTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, such a device may be implemented in hardware, firmware or software, or some combination of at least two of the same. It should be noted that the functionality associated with any particular controller may be centralized or distributed, whether locally or remotely.

Moreover, various functions described below can be implemented or supported by one or more computer programs, each of which is formed from computer readable program code and embodied in a computer readable medium. The terms “application” and “program” refer to one or more computer programs, software components, sets of instructions, procedures, functions, objects, classes, instances, related data, or a portion thereof adapted for implementation in a suitable computer readable program code. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive, a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable memory device.

Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 illustrates an example of a wireless communication system according to embodiments of the disclosure;

FIG. 2 illustrates an example of a structure of an electronic device according to embodiments of the disclosure;

FIGS. 3A and 3B illustrate examples of a structure including a power supply or supply modulator according to embodiments of the disclosure;

FIGS. 4A and 4B illustrate examples of a structure including a DC/DC converter and a linear amplifier according to embodiments of the disclosure;

FIGS. 5A and 5B illustrate examples of a structure including a distributed supply modulator according to embodiments of the disclosure;

FIG. 6 illustrates an example of a structure including an alternating current (AC)-coupled supply modulator according to embodiments of the disclosure;

FIGS. 7A and 7B illustrate examples of a specific structure of an AC-coupled supply modulator according to embodiments of the disclosure;

FIGS. 8 to 10 each illustrate another example of AC-coupled supply modulator according to embodiments of the disclosure; and

FIG. 11 illustrates an example of a functional configuration of an electronic device including a power amplifier coupled to an AC-coupled supply modulator according to various embodiments of the disclosure.

### DETAILED DESCRIPTION

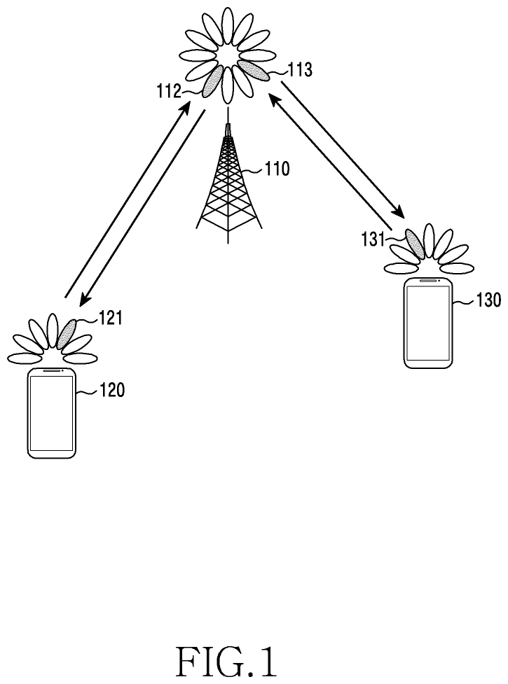

FIGS. 1 through 11, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged system or device.

Hereinafter, exemplary embodiments of the disclosure will be described in detail with reference to the accompanying drawings. It should be noted that, in the accompanying drawings, the same or like elements are designated by the same or like reference signs as much as possible. In addition, a detailed description of known functions or configurations that may make the subject matter of the disclosure unclear will be omitted.

In describing embodiments set forth herein, descriptions related to technical contents well-known in the art and not associated directly with the disclosure will be omitted. Such an omission of unnecessary descriptions is intended to prevent obscuring of the main idea of the disclosure and more clearly transfer the main idea.

For the same reason, in the accompanying drawings, some elements may be exaggerated, omitted, or schematically illustrated. Also, the size of each element does not completely reflect the actual size. In the respective drawings, the same or corresponding elements are assigned the same reference numerals.

The advantages and features of the present disclosure and ways to achieve them will be apparent by making reference to embodiments as described below in detail in conjunction with the accompanying drawings. However, the disclosure is not limited to the embodiments set forth below, but may be implemented in various different forms. The following embodiments are provided only to completely disclose the disclosure and inform those skilled in the art of the scope of the disclosure, and the disclosure is defined only by the scope of the appended claims. Throughout the specification, the same or like reference signs indicate the same or like elements.

Herein, it will be understood that each block of the flowchart illustrations, and combinations of blocks in the flowchart illustrations, can be implemented by computer program instructions. These computer program instructions can be provided to a processor of a general-purpose computer, special purpose computer, or other programmable data processing apparatus to produce a machine, such that the instructions, which execute via the processor of the computer or other programmable data processing apparatus, create means for implementing the functions specified in the flowchart block or blocks. These computer program instructions may also be stored in a computer usable or computer-readable memory that can direct a computer or other programmable data processing apparatus to function in a particular manner, such that the instructions stored in the computer usable or computer-readable memory produce an article of manufacture including instruction means that implement the function specified in the flowchart block or blocks. The computer program instructions may also be loaded onto a computer or other programmable data processing apparatus to cause a series of operational steps to be performed on the computer or other programmable apparatus to produce a computer implemented process such that the instructions that execute on the computer or other programmable apparatus provide steps for implementing the functions specified in the flowchart block or blocks.

Furthermore, each block in the flowchart illustrations may represent a module, segment, or portion of code, which includes one or more executable instructions for implementing the specified logical function(s). It should also be noted that in some alternative implementations, the functions noted in the blocks may occur out of the order. For example, two blocks shown in succession may in fact be executed substantially concurrently or the blocks may sometimes be executed in the reverse order, depending upon the functionality involved.

As used in embodiments of the disclosure, the term “unit” refers to a software element or a hardware element, such as a field programmable gate array (FPGA) or an application specific integrated circuit (ASIC), and the “unit” may perform certain functions. However, the “unit” does not always have a meaning limited to software or hardware. The “unit” may be constructed either to be stored in an addressable storage medium or to execute one or more processors. Therefore, the “unit” includes, for example, software elements, object-oriented software elements, class elements or task elements, processes, functions, properties, procedures, sub-routines, segments of a program code, drivers, firmware, micro-codes, circuits, data, database, data structures, tables, arrays, and parameters. The elements and functions provided by the “unit” may be either combined into a smaller number of elements, or a “unit,” or divided into a larger number of elements, or a “unit.” Moreover, the elements and “units” may be implemented to reproduce one or more CPUs within a device or a security multimedia card.

The embodiments of the disclosure as described below may also be applied to other communication systems having similar technical backgrounds or channel types to the embodiments of the disclosure. Furthermore, based on determinations by those skilled in the art, the embodiments of the disclosure may also be applied to other communication systems through some modifications without significantly departing from the scope of the disclosure.

In the following description, terms for identifying access nodes, terms referring to network entities or network functions (NFs), terms referring to messages, terms referring to interfaces between network entities, terms referring to various identification information, and the like are illustratively used for the sake of descriptive convenience. Therefore, the disclosure is not limited by the terms as described below, and other terms referring to subjects having equivalent technical meanings may also be used.

In the following description, some of terms and names defined in the 3rd generation partnership project (3GPP) standards may be used for the sake of descriptive convenience. However, the disclosure is not limited by these terms and names, and may be applied in the same way to systems that conform other standards. In particular, the disclosure may be applied to the 3GPP 5th generation mobile communication standards (e.g., 5GS and NR).

FIG. 1 illustrates a wireless communication system according to embodiments of the disclosure. FIG. 1 illustrates a base station 110, a user equipment (UE) 120, and a UE 130, as some of nodes that use radio channels in a wireless communication system. Although FIG. 1 illustrates only one base station, other base stations identical or similar to the base station 110 may be further included.

The base station 110 is a network infrastructure that provides the UEs 120 and 130 with radio access. The base station 110 has coverage defined as a certain geographical area, based on a distance over which a signal can be transmitted. The base station 110 may be referred to as an “access point (AP),” an “eNodeB (eNB),” a “5th generation node (5G node),” a “wireless point,” a “transmission/reception point (TRP),” or any other term having a technical meaning equivalent thereto, in addition to the term “base station.”

Each of the UE 120 and the UE 130 is a device used by a user and performs communication with the base station 110 via a radio channel. In some cases, at least one of the UE 120 and the UE 130 may be operated without a user's involvement. That is, at least one of the UE 120 and the UE 130 may be a device performing machine-type communication (MTC), and may not be carried by a user. Each of the UE 120 and the UE 130 may be referred to as a “user equipment (UE),” a “mobile station,” a “subscriber station,” a “customer-premises equipment (CPE),” a “remote terminal,” a “wireless terminal,” an “electronic device,” a “user device,” or any other term having a technical meaning equivalent thereto, in addition to the term “terminal.”

The base station 110, the UE 120, and the UE 130 may transmit and receive wireless signals in millimeter wave (mmWave) bands (e.g., 28 GHz, 30 GHz, 38 GHz, and 60 GHz). In regard of this, the base station 110, the UE 120, and the UE 130 may perform beamforming in order to improve a channel gain. The beamforming may include transmission beamforming and reception beamforming. That is, the base station 110, the UE 120, and the UE 130 may assign directivity to transmission or reception signals. To this end, the base station 110 and the UEs 120 and 130 may select serving beams 112, 113, 121, and 131 through a beam search procedure or a beam management procedure. After the serving beams 112, 113, 121, and 131 are selected, subsequent communication may be performed through a resource having a quasi co-located (QCL) relationship with a resource in which the serving beams 112, 113, 121, and 131 have been transmitted.

According to an embodiment of the disclosure, a supply modulator for improving the efficiency of a power amplifier or a structure including the same may be used in an electronic device that transmits or receives a signal in the mmWave band. Without being limited thereto, the structure including the supply modulator according to various embodiments may be used in a system including not only the commonly discussed frequency range (FR) 1 band (e.g., Sub 6 GHz), but also a higher frequency band, the FR3 band (e.g., 7 to 8 GHz). For example, when the base station 110 of FIG. 1 transmits or receives a signal, the supply modulator or the structure including the same, disposed in the base station 110, may include all or part of the structure of an amplifier according to various embodiments of the disclosure. As another example, when the UEs 120, 130 of FIG. 1 transmit or receive a signal, the supply modulator or the structure including the same, disposed in the UEs 120, 130, may include all or part of the structure of an amplifier according to an embodiment of the disclosure.

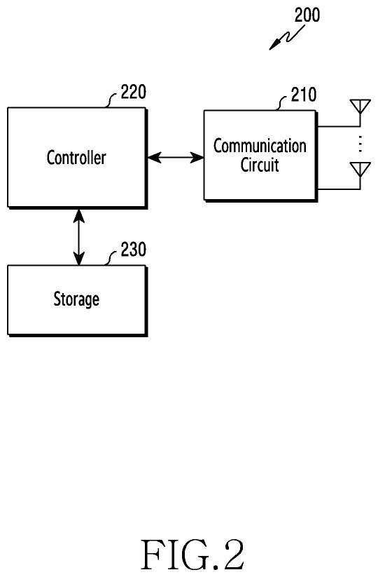

FIG. 2 illustrates an example of the structure of an electronic device according to embodiments of the disclosure. The electronic device of FIG. 2 may include an electronic device disposed in the base station or UE described in FIG. 1. In addition, the electronic device including each component of FIG. 2 may include, for example, a direct current (DC)/DC converter, a supply modulator, a switch, or a power amplifier according to various embodiments of the disclosure.

An example of the functional structure of an electronic device (or hardware device) according to embodiments of the disclosure is illustrated with reference to FIG. 2. As used herein, the terms “. . . unit” or “. . . device” refer to a unit that processes at least one function or operation, and may be implemented in hardware, software, or a combination of hardware and software. In an embodiment, the electronic device includes a communication circuit 210, a storage 230, and a controller 220.

The communication circuit 210 performs functions for transmitting and receiving signals or data via a wireless channel or a wired channel. However, without being limited thereto, the communication circuit 210 may also include configurations for lines through which various units of the disclosure (e.g., a power amplifier) transmit and receive various signals with other circuit units.

As described above, the communication circuit 210 transmits and receives signals. In an embodiment, the communication circuit 210 may transmit and receive signals between circuits or network units. Accordingly, all or part of the communication circuit 210 may be referred to as a transmitter, a receiver, or a transceiver. In addition, in the following description, the transmission and reception performed via lines and wireless or wired channels are used to mean that such processing, as described above, is carried out by the communication circuit 210.

The storage 230 stores data such as basic programs, application programs, and configuration information for the operation of the electronic device. The storage 230 may be configured with volatile memory, non-volatile memory, or a combination of volatile and non-volatile memory. The storage 230 may provide the stored data in response to a request from the controller 220.

The controller 220 controls the overall operations of the electronic device (for example, including circuit units such as a power amplifier). For example, the controller 220 transmits and receives signals via the communication circuit 210. The controller 220 also records data to and reads data from the storage 230. To this end, the controller 220 may include at least one processor (or controller) or microprocessor, or may be a part of a processor. According to various embodiments, the controller 220 may perform control such that various circuit units identify and generate signals to be transmitted and received. For example, the controller 220 may control each circuit unit to perform operations according to various embodiments and structures described hereinafter.

According to various embodiments, the electronic device illustrated in FIG. 2 may include a programmable hardware device or a logical software device. For example, the electronic device may include at least one of various programmable circuit devices, such as an application-specific integrated circuit (ASIC), a network interface controller (NIC), an intelligence processing unit (IPU), a data processing unit (DPU), or CPU.

Hereinafter, according to various embodiments of the disclosure, the electronic device may be replaced and referred to by various expressions having substantially the same meaning, while including various circuit units operating to achieve the effects of the disclosure, such as a hardware device, a direct current (DC) converter (e.g., a DC/DC converter), a voltage modulator or generator, a switch, a supply modulator, a first device, or a second device.

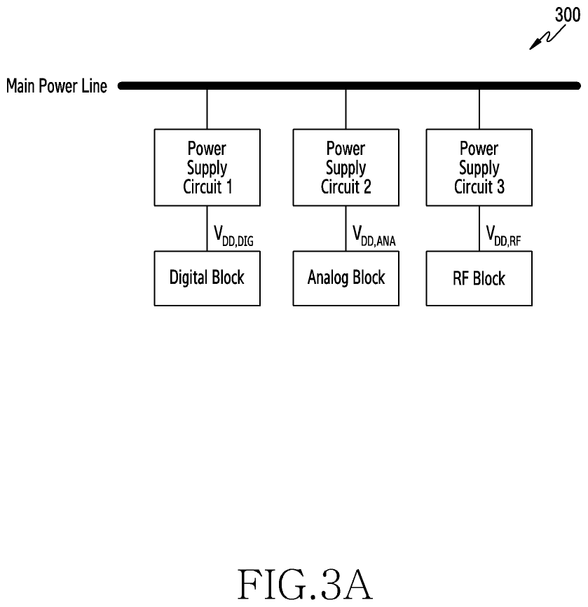

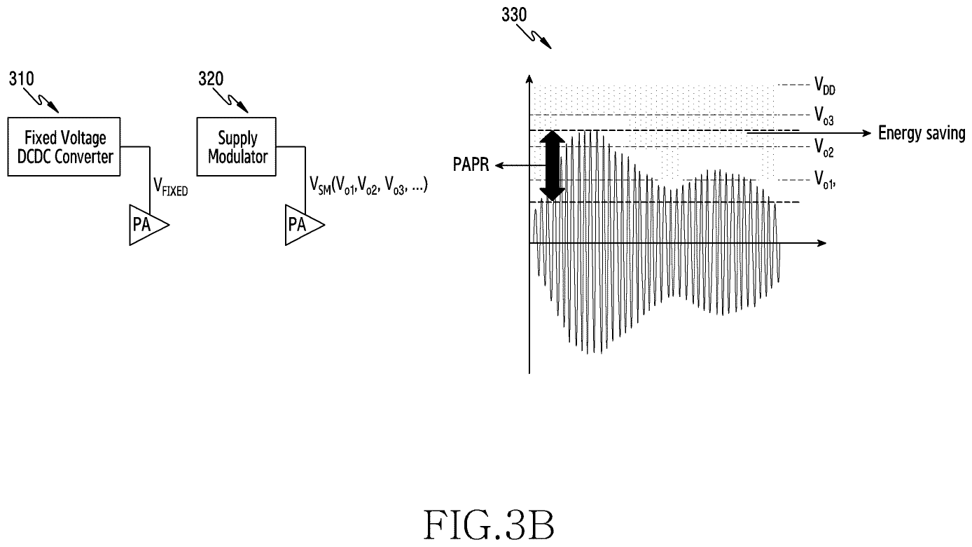

FIGS. 3A and 3B illustrate examples of a structure including a power supply or a supply modulator according to embodiments of the disclosure, and the effects thereof.

Referring to FIG. 3A, an electronic device 300 may operate by receiving external power from a main power line. The electronic device may include one or more circuits that respectively perform various operations, and the circuits included in the electronic device may include, for example, a digital circuit, an analog circuit, or a radio frequency (RF) circuit. In this case, the voltage for each of the circuits described above to operate may differ from one another. To this end, a circuit that converts the voltage supplied from the external power source into a voltage by each circuit to supply power may be referred to as a power converter circuit. More specifically, as described above, in order to improve the energy efficiency of a single circuit, a technique may be performed for adaptively adjusting the voltage level to supply the power for each circuit. Such a technique for adjusting the output voltage of the power converter circuit may be referred to as supply modulation, and a power converter circuit implementing such a supply modulation function may be referred to as a supply modulator.

Referring to FIG. 3B, unlike a DC/DC converter 310 that provides a fixed voltage (e.g., V_fixed) to a power amplifier, a supply modulator 320 may provide an adaptive voltage (e.g., V_o1, V_o2, V_o3, . . . ) depending on the use of the power amplifier or the signal in which the power amplifier operates. In particular, the supply modulator may be efficiently used in advanced communication systems that employ high data rates and techniques such as high-order quadrature amplitude modulation (QAM) or orthogonal frequency-division multiplexing (OFDM) for achieving the same.

Referring to the signal waveform graph 330 according to recent communication system techniques, as the signal corresponds to a higher band or has higher complexity, the difference between the peak power and the average power (e.g., peak-to-average power ratio (PAPR)) may increase, which may lead to a decrease in the energy efficiency of the power amplifier. To address this, a supply modulator may be used. The supply modulator may save energy by adaptively providing a variable voltage (e.g., V_o1, V_o2, V_o3, . . . ) to the power amplifier according to the power level corresponding to each point in time of the signal, instead of providing a fixed voltage (e.g., a fixed external power source V_DD).

As described above, in order to prevent situations in which the performance of a circuit actually receiving power (e.g., a power amplifier) deteriorates, the supply modulator may be used to adjust its output voltage at a sufficiently high speed according to the signal required by the power amplifier, and the supply modulator itself is also used to have high energy efficiency.

Accordingly, compared to the performance of commonly used supply modulators, the level by 6G communication systems and subsequent evolving communication systems is gradually increasing. The disclosure provides a supply modulator having a new structure, or an electronic device (e.g., a radio frequency integrated circuit (RFIC)) including the same, for reducing energy consumption while maintaining the communication performance of a base station. However, according to various embodiments of the disclosure, the supply modulator described in detail hereinafter may simply be referred to as a supply modulator, or may be referred to by various terms such as a supply modulator for high efficiency and fast transient current. In addition, although the supply modulator according to the disclosure may generally be used in a base station device in which a high voltage is used, the supply modulator may, without being limited thereto, also be applied to a UE device so as to perform substantially the same function.

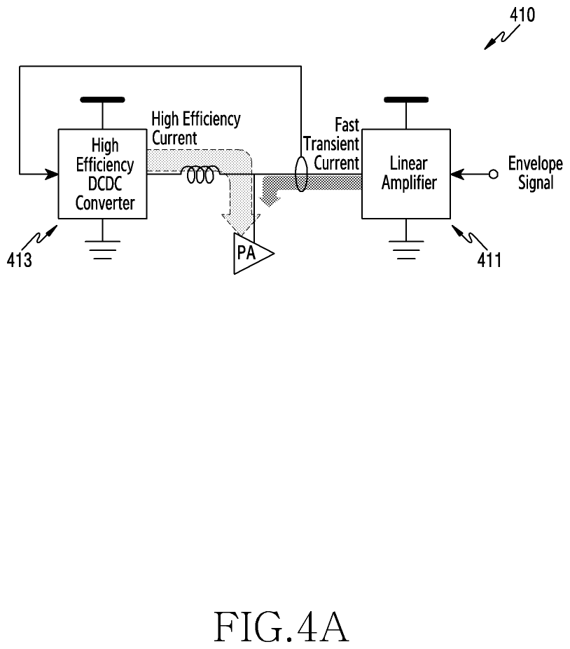

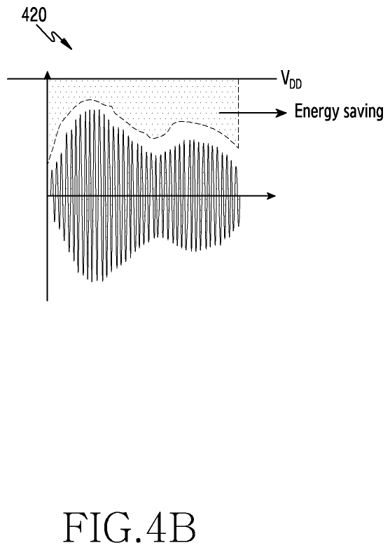

FIGS. 4A and 4B illustrate examples of a structure including a DC/DC converter and a linear amplifier according to embodiments of the disclosure. More specifically, FIG. 4A illustrates the structure of a linear amplifier assisted supply modulator (LASM) 410 including a linear amplifier.

Referring to FIG. 4A, the LASM 410 may generally be used primarily to increase the energy efficiency of a power amplifier included in a UE. The LASM 410 may include a DC/DC converter (e.g., a high efficiency DC/DC converter) 413 and a linear amplifier 411. Here, the DC/DC converter 413 is connected in parallel to the linear amplifier 411 and may transfer current to the power amplifier to generate a voltage. More specifically, according to the input signal for amplification by the power amplifier, the LASM 410 needs to control the output voltage (i.e., the voltage generated by the current transmitted to the power amplifier). To this end, the LASM may receive an envelope signal and adjust the supply voltage so as to improve the energy efficiency of the power amplifier.

For example, the DC/DC converter 413 and the linear amplifier 411 included in the LASM 410 may each receive an envelope signal (or the DC/DC converter 413 may receive the envelope signal via the linear amplifier 411) and, based thereon, may transmit current for adjusting the voltage level to the power amplifier. However, while the current provided by the DC/DC converter 413 may have good energy efficiency, the speed of controlling the voltage level of such current may fall short of the requirements according to variations in the envelope signal. In contrast, the linear amplifier 411 may provide a rapidly varying current (e.g., fast transient current) so as to enable fast modulation of the output voltage in accordance with the changing signal.

Referring to the signal waveform graph 420 of the LASM 410 in FIG. 4B, the voltage supplied to the power amplifier may be controlled to approximate the waveform of the envelope signal, according to the current transmitted by the DC/DC converter 413 and the current transmitted by the linear amplifier 411. Through this, the power amplifier may save energy compared to the case of operating with a fixed voltage (e.g., V_dd). However, the linear amplifier 411 included in the LASM 410 may not be used with wideband communication signals of 200 MHz or greater due to bandwidth limitations.

In addition, the LASM 410 including the linear amplifier 411 may not be commercially adopted for devices such as base stations. For example, a power amplifier disposed in a base station may operate at a higher voltage (e.g., 30-48 V for a base station power amplifier) compared to a UE (e.g., 2-5 V for a UE power amplifier). To this end, the linear amplifier may supply more current than the capability thereof in order to satisfy the voltage level corresponding to the envelope signal, namely, to follow the waveform of the envelope signal, which may in turn cause a significant reduction in energy efficiency.

According to various embodiments of the disclosure, a new structure of a supply modulator may be provided to meet the requirements of a high-frequency band or a base station power amplifier and to address the above-described problems.

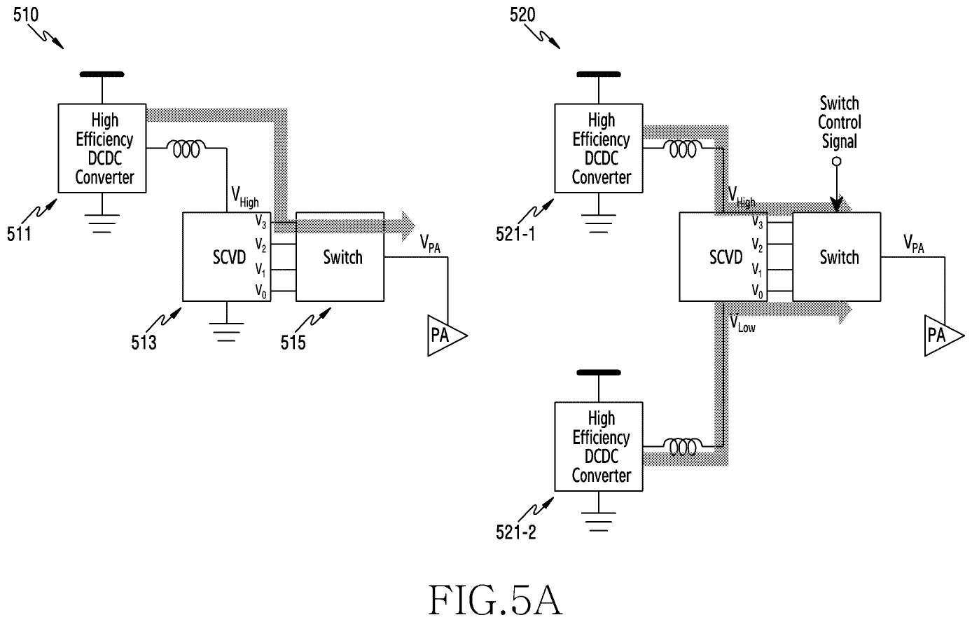

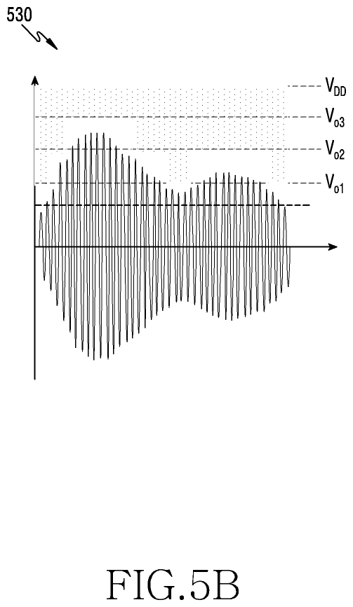

FIGS. 5A and 5B illustrate examples of a structure including a distributed supply modulator according to embodiments of the disclosure and the effects thereof. More specifically, FIG. 5A illustrates the structure of a series-connected discrete supply modulator (SCDSM) 510, 520 including a switched capacitor voltage divider (SCVD), and FIG. 5B illustrates the effect of energy saving achieved by the structure.

Referring to FIG. 5A, the SCDSM 510 (e.g., a first structure), 520 (e.g., a second structure) may generally be used to improve energy efficiency in high-voltage power amplifiers, such as those used in base stations. The SCDSM 510, 520 may include a DC/DC converter (e.g., a high-efficiency DC/DC converter 511, 521-1, 521-2), an SCVD 513, and a switch 515. The DC/DC converter 511, 521-1, and 521-2 may provide current to be supplied to the power amplifier and, at the same time, serve to generate a reference voltage for a voltage generator, such as the SCVD 513. The SCVD 513 may receive the reference voltage according to the current provided from the DC/DC converter and, based thereon, may generate one or more voltage levels having equal spacing. The switch 515 may select one of the various voltage levels generated by the SCVD 513 according to the envelope signal, and perform the power supply function of outputting and delivering the selected voltage level to the power amplifier.

More specifically, referring to the first structure 510 of FIG. 5A, the DC/DC converter 511 may convert current received from an external power source into a DC current with high energy efficiency and deliver the DC current to the SCVD 513. The current provided by the DC/DC converter 511 may serve as a reference voltage for the voltage and current generated by the SCVD 513. The SCVD 513 connected to the DC/DC converter 511 may generate one or more voltages (e.g., V_0, V_1, V_2, V_3) having equal spacing, based on the current received from the DC/DC converter. Accordingly, the switch 515 connected to the SCVD 513 may select, from among the one or more voltages generated by the SCVD 513, the voltage corresponding to each point in time according to the envelope signal, and may transmit, to the power amplifier, current for supplying the selected voltage. To this end, although not shown in FIG. 5A, the SCVD 513 may separately receive the envelope signal or a switch control signal.

In addition to the first structure 510, a second structure 520 may be considered to implement a more efficient SCDSM. Referring to the second structure 520 of FIG. 5A, the first DC/DC converter 521-1 and the second DC/DC converter 521-2 may convert current received from an external power source into a DC current with high energy efficiency and deliver the DC current to the SCVD. The current provided by the DC/DC converters 521-1 and 521-2 may serve as a reference voltage for the voltage and current generated by the SCVD. The SCVD connected to the DC/DC converters 521-1 and 521-2 may generate one or more voltages (e.g., V_0, V_1, V_2, V_3) having equal spacing, based on the current received from the DC/DC converters. Here, unlike the first structure 510, the SCVD of the second structure 520 may be connected to the second DC/DC converter 521-2 instead of ground, thereby receiving additional current. The current transmitted by the second DC/DC converter 521-2 may provide a lower reference voltage (e.g., V_Low) that serves as a lower reference voltage among the voltages generated by the SCVD, which is a voltage generator. For example, the one or more voltages generated by the SCVD may have a value that is obtained by adding equal spacing, based on the voltage (e.g., V_Low) delivered by the second DC/DC converter in common. That is, compared to the first structure 510, the second structure 520 may enable voltage generation and supply modulation for a higher voltage. Subsequently, the switch connected to the SCVD may select, from among the one or more voltages generated by the SCVD, the voltage corresponding to each point in time according to the envelope signal, and transmit, to the power amplifier, current for supplying the selected voltage. To this end, although not shown in FIG. 5A, the switch 515 may separately receive the envelope signal or a switch control signal.

Referring to the signal waveform graph 530 of the SCDSM 510, 520 in FIG. 5B, the current transmitted by the DC/DC converter 511, 521-1, 521-2, the voltages of the SCVD 513, generated accordingly, and the voltage selected by the switch 515 and supplied to the voltage amplifier may be discontinuously controlled to match the waveform of the envelope signal, thereby enabling the power amplifier to be adaptively utilized according to the voltage situation and save energy compared to the case according to a fixed voltage (e.g., V_dd).

However, according to the SCDSM 510, 520, all of the current supplied from the DC/DC converter may be supplied to the power amplifier via the SCVD and the switch. In this case, the supplied current may experience the resistance components of the SCVD and the switch. Because such resistance in the SCVD and the switch may cause power loss, larger SCVD and switch devices may be used in order to reduce loss and resistance. Consequently, the SCVD and the switch need to be implemented with transistors of greater size, which in turn can cause problems of larger area and higher cost. In addition, because the voltage levels that may be generated and provided to the power amplifier by the SCDSM 510 (e.g., a first structure), 520 (e.g., a second structure) are ultimately limited by the reference voltage generated from the DC/DC converter, more diverse voltages may not be generated.

In consideration of the above-described problems, various embodiments of the disclosure provides a supply modulator that may be applied to applications requiring high voltage, such as base stations, and that performs high energy efficiency and fast output voltage modulation, which are described in detail below.

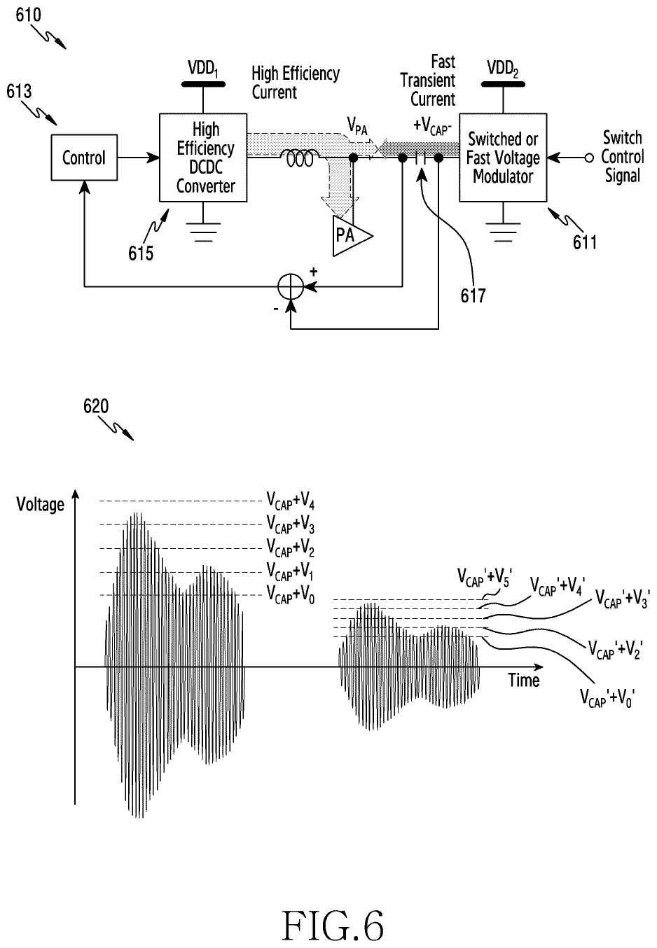

FIG. 6 illustrates an example of a structure including an alternating current (AC)-coupled supply modulator according to embodiments of the disclosure, and the effects thereof. More specifically, the supply modulator 610 of FIG. 6 illustrates a structure including a switched or fast voltage modulator (SFVM) 611, a loop controller 613, a high-efficiency DC/DC converter 615, and an AC-coupled capacitor 617, as well as the effect of energy saving achieved by the structure. Hereinafter, according to various embodiments of the disclosure, the terms used above are merely examples and are not limited thereto. For example, the SFVM, loop controller, DC/DC converter, and AC-coupled capacitor may be referred to by various terms having substantially the same meaning as voltage modulator, controller, DC/DC converter, and capacitor, respectively.

Referring to FIG. 6, according to an embodiment, a supply modulator (for example, referred to as an AC-coupled parallel combined supply modulator in the sense that a DC/DC converter and a voltage modulator are connected in parallel to supply power to a load, such as a power amplifier) connected to a power amplifier may include a DC/DC converter 615. In an embodiment, the DC/DC converter 615 is a block for supplying high-efficiency, high-output DC current, and may include commonly used switched-inductor-based DC/DC converters such as a buck converter, a 3-level converter, or a buck-boost converter. More specifically, the DC/DC converter 615 may provide DC current for generating a voltage desired by the power amplifier, based on the voltage supplied from an external power source (e.g., VDD_1), and may also provide current received from the controller 613 to the capacitor 617 so as to perform an operation of maintaining a constant voltage across both terminals of the capacitor 617. Although not shown in FIG. 6, the DC/DC converter 615 may also receive an external signal, such as an envelope signal, and provide voltage to the power amplifier by transmitting current based on the envelope signal. In addition, referring to FIG. 6, although an inductor is illustrated on the line between the node connecting the DC/DC converter 615, the power amplifier, and the capacitor 617 and the DC/DC converter 615, this is merely an example and may be omitted.

Referring to FIG. 6, the supply modulator 610 may include a controller 613. In an embodiment, the controller 613 is a block that controls the DC/DC converter by sensing the voltage across both terminals of the capacitor 617 (e.g., V_CAP) in order to maintain the voltage across both terminals of the capacitor 617 constant, and may include a pulse width modulation (PWM) controller, a hysteresis controller, or a constant-on-time controller. More specifically, the controller 613 may receive the current provided from the positive terminal of the capacitor 617 and the current provided from the negative terminal of the capacitor 617 via a summing node, identify the voltage across both terminals of the capacitor 617, and generate a signal for controlling the voltage.

Referring to FIG. 6, the supply modulator 610 may include a voltage modulator 611. In an embodiment, the voltage modulator 611 may perform a function substantially similar or identical to that of the SCVD in FIG. 5A. For example, the voltage modulator 611 may receive an external control signal, such as an envelope signal, and generate a desired voltage according to the modulation signal input to the power amplifier. Accordingly, during voltage modulation, the voltage modulator 611 may provide fast transient current to the power amplifier via the capacitor 617. For example, the voltage modulator 611 is a block that supplies current (e.g., fast transient current) at the voltage switching point to perform rapid voltage switching, and may include an SCVD, at least one low-dropout (LDO) regulator, and the like.

Referring to FIG. 6, the supply modulator 610 may include a capacitor 617. In an embodiment, the capacitor 617 is a block for maintaining the offset of the voltage supplied to the power amplifier, and may operate, when the voltages at both terminals are the same, as an open element such that the DC current of the DC/DC converter 615 is not transmitted to the voltage modulator 611. More specifically, when the voltage across both terminals of the capacitor 617 is maintained constant under the control of the controller 613, the current transmitted to the power amplifier may include only the DC current provided from the DC/DC converter 615. That is, this may be considered a state in which there is no change in the voltage of the input signal to the power amplifier, and therefore the power amplifier may receive only the DC current provided from the DC/DC converter 615. When a change occurs in the voltage of the input signal to the power amplifier, a difference may occur in the voltage across both terminals of the capacitor 617. In this case, to accommodate the voltage variation according to the input signal, the voltage modulator 611 may deliver transient current to the power amplifier.

According to various embodiments of the disclosure, the supply modulator 610 may increase the energy efficiency of the power amplifier by switching the supply voltage of the power amplifier in accordance with the envelope signal of the input signal to the power amplifier.

For example, in general, an SCVD or LDO included in the voltage modulator 611 may have lower energy efficiency compared to a buck converter or a buck-boost converter included in the DC/DC converter. Therefore, a method in which the DC/DC converter provides most of the current supplied to the power amplifier may be effective in terms of the energy efficiency of the overall circuit. Accordingly, the supply modulator 610 of the disclosure may disconnect the DC line between the power amplifier and the voltage modulator by means of the capacitor 617, and thus, when a constant voltage is maintained in the power amplifier, may perform control such that all of the current for supply is provided by the DC/DC converter, thereby managing energy efficiency more effectively.

In addition, according to various embodiments, via an improved structure of the voltage modulator 611, fast supply modulation may be achieved even for wideband signals, and by disconnecting the DC line via the capacitor 617, the voltage modulator 611 may be controlled to supply current only during voltage switching. Accordingly, power loss consumed in the voltage modulator 611 may be reduced, and likewise, the size of the transistors therefore may also be reduced, which in turn reduces area and, consequently, cost.

According to various embodiments, referring to the effect graph 620 of the supply modulator 610, the supply modulator 610 may generate various voltage levels depending on the situation. The controller 613 may control the voltage across both terminals of the capacitor 617. More specifically, the controller 613 may variably control the capacitor voltage (e.g., V_CAP), which serves as the offset for voltage generation, according to the scale of the input modulation signal. In addition, the voltage modulator may control the spacing between one or more voltage levels generated according to the input modulation signal. That is, the supply modulator 610 according to the disclosure may generate various voltage levels suitable for the waveform of various input signals, based on the control of the above-described voltages.

Hereinafter, according to various embodiments of the disclosure, a more specific structure of a supply modulator and operation thereof, as well as examples of modifications of various supply modulator structures, are specifically described.

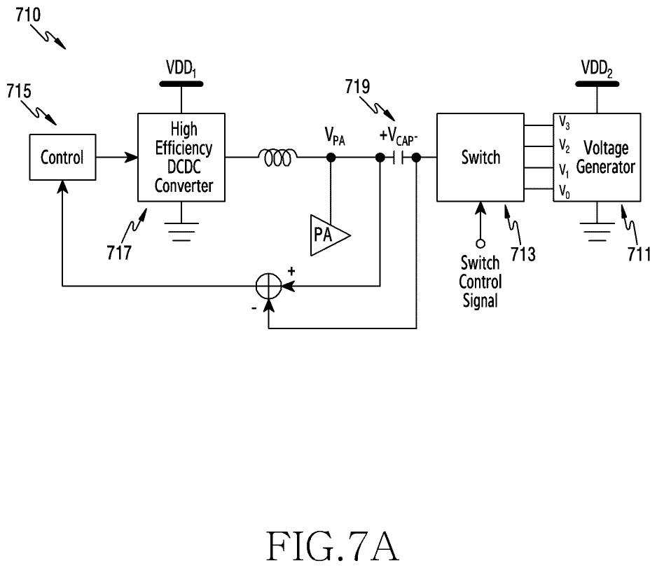

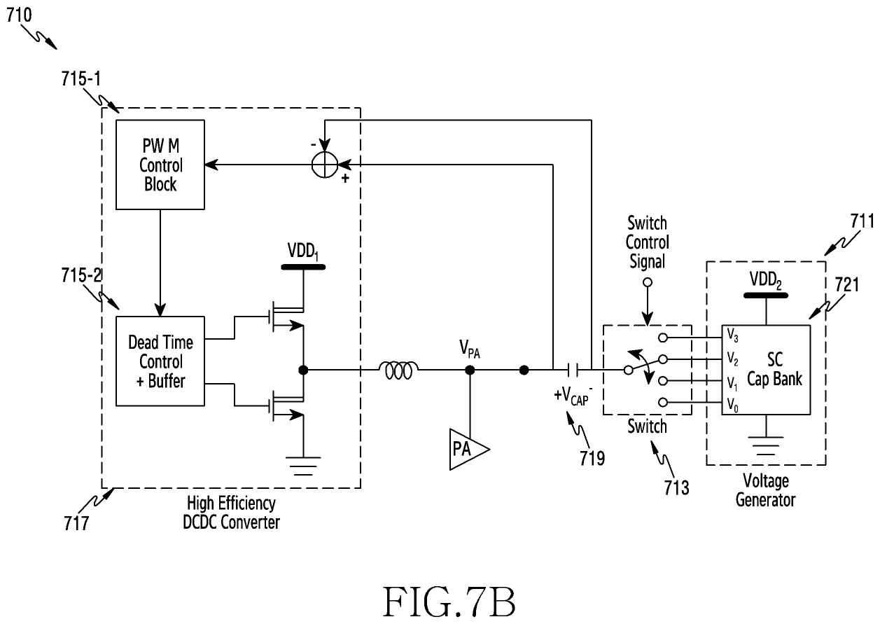

FIGS. 7A and 7B illustrate examples of a more specific structure of an AC-coupled supply modulator according to embodiments of the disclosure, and the effects thereof. Referring to FIGS. 7A and 7B, the structure of more specific units included in the supply modulator and the operations of each unit are described in detail.

Referring to FIG. 7A, the supply modulator 710 of FIG. 7A may include a voltage generator 711 connected to an external power source, a switch 713 that receives a control signal for switching (e.g., an external signal such as an envelope signal), a controller 715, a high-efficiency DC/DC converter 717 connected to the external power source, and a capacitor 719. In an embodiment, the voltage generator 711 and the switch 713 may correspond to the SFVM of FIG. 6. In addition, the controller 715, the DC/DC converter 717, and the capacitor 719 may respectively correspond to the loop controller, the high-efficiency DC/DC converter, and the AC-coupled capacitor in FIG. 6. Accordingly, the unit performing the function corresponding to FIG. 6 and the operations of the unit may be applied identically or similarly, and a detailed description of the overlapping content with the above-described content will be omitted.

The voltage generator 711 of FIG. 7A may perform the same or similar function as the SCVD of FIG. 5A, and the switch 713 may perform the same or similar function as the switch of FIG. 5A. In this case, the voltage generator 711 may also be referred to as an SCVD or a capacitor bank. The voltage generator 711 may receive a reference voltage according to the current provided from an external power source and, based thereon, may generate one or more voltage levels having equal spacing. Subsequently, the switch 713 may receive a control signal for switching and, accordingly, may select one of the various voltage levels generated by the voltage generator 711. For example, the switch 713 may select a desired voltage according to a modulation signal input to the power amplifier, and output the selected voltage level to provide fast transient current to the power amplifier via the capacitor 719.

A more specific structure of the DC/DC converter 717 included in the supply modulator 710 is illustrated with reference to FIG. 7B. The DC/DC converter 717 included in the supply modulator 710 may include a PWM control block 715-1, which performs the functions of the controller 715 and the DC/DC converter 717, and a dead time block 715-2 for controlling dead time.

Referring to FIG. 7B, since the non-overlapping gate driver of the DC/DC converter may have a fixed dead time, conduction loss of a diode and the like may occur. To prevent efficiency degradation caused by such loss, a PWM-based DC/DC converter including a dead time control block, such as that shown in FIG. 7B, may be used. However, according to various embodiments, FIG. 7B merely describes an example in which the DC/DC converter 717 is a buck converter, and the DC/DC converter 717 may include various commonly used switched-inductor-based DC/DC converters such as a buck converter, a 3-level converter, or a buck-boost converter. In addition, the PWM control block included in the buck converter is merely an example, and may include, as a control block for controlling the voltage across both terminals of the capacitor, various control blocks having similar functions, such as a hysteresis controller or a constant-on-time controller.

Although not shown in FIG. 7B, converters that may be applied to the DC/DC converter 717 are described in more detail below.

In an embodiment, a buck converter may refer to a DC switch-mode power supply device that stabilizes the input voltage of an unregulated DC power source and reduces the voltage to a lower output voltage. A buck converter has the advantage of being able to output most of the input power as is, and thus may achieve very high conversion efficiency.

In an embodiment, a boost converter may refer to a DC switch-mode power supply device that increases the input voltage of an unregulated DC power source to a stabilized, lower output voltage. A boost converter may include an inductor, a diode, a capacitor, and a power switch, similar to a buck converter, but these components are positioned differently from those of a buck converter.

In an embodiment, a buck-boost converter may include a structure in which a buck converter and a boost converter are integrated, and may refer to a power supply device capable of stepping down or up a voltage. Since a buck-boost converter may step up or down an input voltage, the buck-boost convert has the advantage of achieving a wide input voltage range and thus high efficiency.

Hereinafter, various structures of the supply modulators described in FIGS. 6 to 7B are described. However, the structures according to each drawing are not separate embodiments, and it should be understood that some units may be integrated or omitted while including units that perform similar functions.

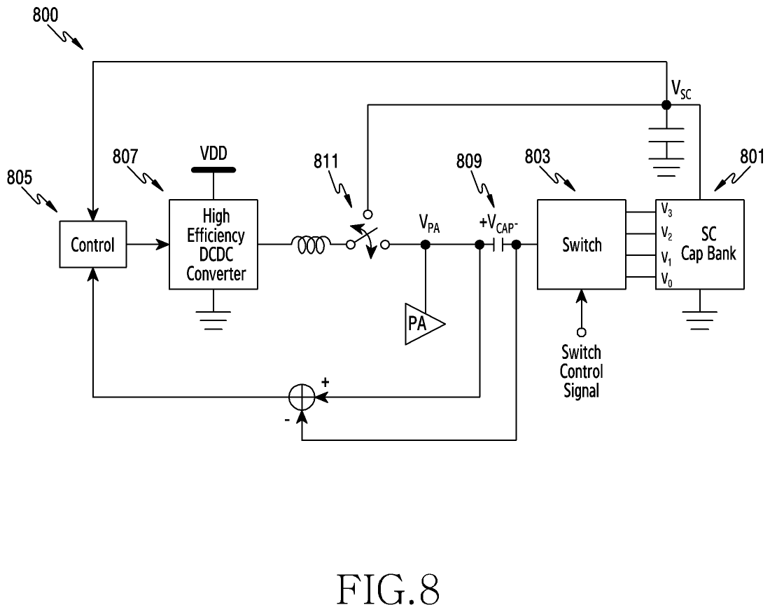

FIGS. 8 to 10 illustrate another example of an AC-coupled supply modulator according to embodiments of the disclosure.

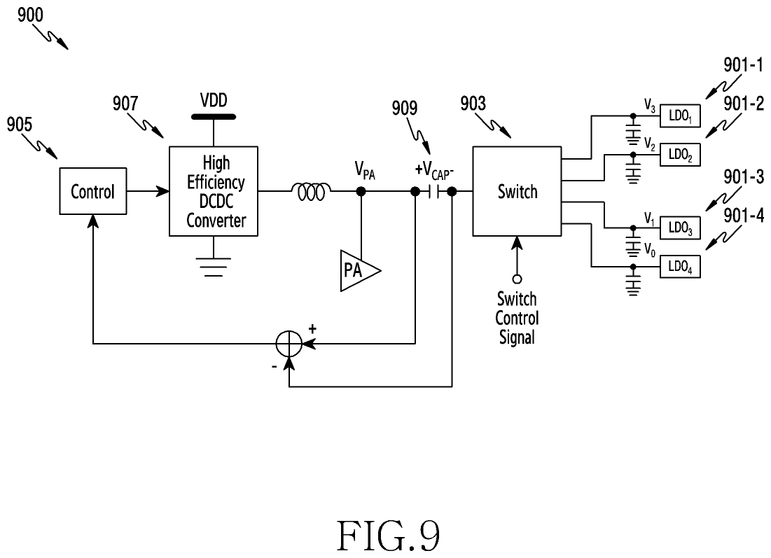

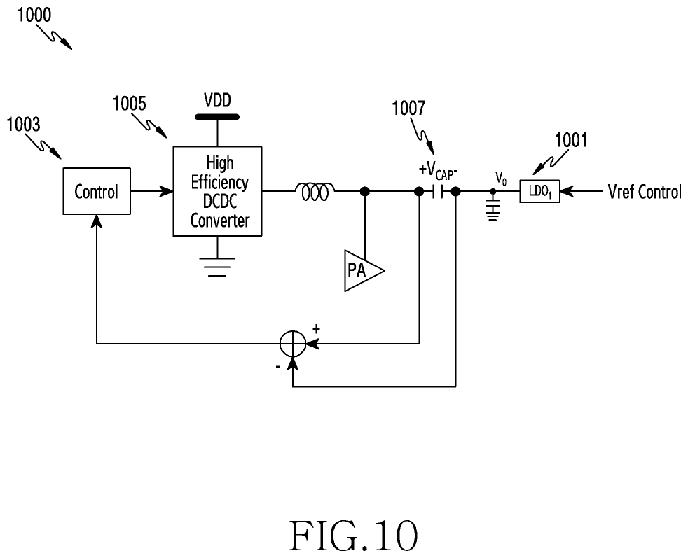

FIG. 8 illustrates a supply modulator 800 including a DC/DC converter 807 implemented in the form of a single-inductor dual-output (SIDO) that is powered by a single external power source. For example, unlike the previously described supply modulators, the supply modulator 800 of FIG. 8 includes only an external power source connected to the DC/DC converter, and the switch or voltage generator may have a structure that does not use the supply of a separate external power source. Such a SIDO-type DC/DC converter may be applied not only to the structures of FIGS. 6 to 7B but also to the structures of FIGS. 9 and 10 described below.

The supply modulator 800 of FIG. 8 may include a voltage generator 801, a switch 803 that receives a control signal for switching (e.g., an external signal such as an envelope signal), a controller 805, a high-efficiency DC/DC converter 807 connected to an external power source, and a capacitor 809. Furthermore, the supply modulator 800 may further include a switching node 811 connected to the DC/DC converter, and may be connected to the power amplifier or to a voltage reference node (e.g., V_SC) connected to the controller 805 and the voltage generator 801. In an embodiment, the voltage generator 801 and the switch 803 may correspond to the voltage generator and the switch in FIGS. 7A and 7B. In addition, the controller 805, the DC/DC converter 807, and the capacitor 809 may respectively correspond to the loop controller, the high-efficiency DC/DC converter, and the AC-coupled capacitor in FIG. 6. Accordingly, the units performing functions corresponding to those of FIG. 6 and the operations of the units may be applied in the same or similar manner, and a detailed description of the overlapping content with the above-described content will be omitted.

Describing the supply modulator 800 of FIG. 8 in more detail, the line between the node connecting the DC/DC converter 807, the power amplifier, and the capacitor 809 and the DC/DC converter 807 may include the switching node 811. In addition, the switching node 811 may be connected with reference to the voltage generator 801 and the voltage reference node. In this case, the voltage reference node may also be connected to the controller 805.

In an embodiment, when the switching node 811 is connected to the line for the power amplifier, the current transmitted from the DC/DC converter 807 may be transmitted to the power amplifier for voltage modulation, as in the aforementioned embodiments. In an embodiment, when the switching node 811 is switched to be connected to the line for the voltage reference node, the current transmitted from the DC/DC converter 807 may be provided to a capacitor that may be disposed between the voltage reference node and ground. The voltage reference node may then provide the generated voltage to the voltage generator 801. In addition, the controller 805 may sense the voltage generated at the voltage reference node and monitor whether the voltage is maintained constantly. The controller 805 may transmit a feedback signal according to the monitoring to control the output current of the DC/DC converter. The current provided to the controller 805 or voltage generator 801 may include a current for providing power to the controller 805 or voltage generator 801, based on the power received by the DC/DC converter 807 from the external power source.

As described above, the switching node 811 may be switched to connect to the node connected to the power amplifier or to the voltage reference node. Accordingly, the voltage generator may receive current and voltage from the external power source connected to the DC/DC converter, without a separate directly connected external power source.

FIG. 9 illustrates a supply modulator 900 including one or more LDO regulators for voltage generation. For example, instead of including the above-described SCVD for the function of the above-described voltage generator, the supply modulator 900 of FIG. 9 may include a plurality of LDO regulators 901-1, 901-2, 901-3, 901-4.

The supply modulator 900 in FIG. 9 may include a plurality of LDO regulators 901-1, 901-2, 901-3, 901-4, a switch 903 that receives a control signal for switching (e.g., an external signal such as an envelope signal), a controller 905, a high-efficiency DC/DC converter 907 connected to an external power source, and a capacitor 909. In an embodiment, the switch 903 may correspond to the switch of FIGS. 7A and 7B, and the controller 905, the DC/DC converter 907, and the capacitor 909 may respectively correspond to the loop controller, the high-efficiency DC/DC converter, and the AC-coupled capacitor in FIG. 6. Accordingly, the units performing functions corresponding to those of FIG. 6 and the operations of the units may be applied in the same or similar manner, and a detailed description of the overlapping content with the above-described content will be omitted.

An LDO regulator may refer to a unit capable of regulating voltage to remain stable even when the potential difference between the input and output is low. In particular, an LDO regulator has significance as a circuit element capable of generating a desired voltage level while minimizing the influence of noise. For example, the plurality of LDO regulators 901-1, 901-2, 901-3, 901-4 of the supply modulator 900 may be implemented to respectively generate different voltage levels (e.g., V_0, V_1, V_2, V_3). In this case, the different voltage levels may have voltage differences with equal spacing.

In an embodiment, the plurality of LDO regulators 901-1, 901-2, 901-3, 901-4 may generate one or more voltages, based on power supplied from an external power source (or from the DC/DC converter in case of the SIDO configuration in FIG. 8), similar to the above-described SCVD. Accordingly, the switch 903 connected to the plurality of LDO regulators 901-1, 901-2, 901-3, 901-4 may select, from among the one or more voltages generated by the plurality of LDO regulators 901-1, 901-2, 901-3, 901-4, the voltage (e.g., V_PA) corresponding to each point in time according to the envelope signal and may transmit, to the power amplifier, current for supplying the selected voltage. To this end, although not shown in FIG. 9, the plurality of LDO regulators 901-1, 901-2, 901-3, 901-4 may each separately receive an envelope signal or a switch control signal serving as a basis for generating the respective voltage levels.

In FIG. 10, the supply modulator 100 may include a single LDO regulator 1001, a controller 1003, a high-efficiency DC/DC converter 1005 connected to an external power supply, and a capacitor 1007. According to an embodiment, the controller 1003, the DC/DC converter 1005, and the capacitor 1007 may respectively correspond to the loop controller, the high-efficiency DC/DC converter, and the AC-coupling capacitor in FIG. 6. Accordingly, the units performing functions corresponding to those of FIG. 6 and the operations of the units may be applied in the same or similar manner, and a detailed description of the overlapping content with the above-described content will be omitted.

As described above with reference to FIG. 9, the LDO regulator may refer to a unit capable of controlling the voltage to remain stable even when the potential difference between the input and output is low. In particular, the LDO regulator has significance as a circuit element capable of generating a desired voltage level while minimizing the influence of noise.

However, unlike the structure of FIG. 9, the supply modulator 1000 of FIG. 10 may include a single LDO regulator 1001. In this case, the LDO regulator 1001 included in the supply modulator 1000 may receive, from the outside, a control signal (for example, V_ref control) for a reference voltage. For example, the control signal received by the LDO regulator 1001 may include a signal that controls the generation of different voltage levels. That is, the control signal received by the LDO regulator 1001 may be substantially similar to the function performed by the switch of FIG. 9.

According to an embodiment, the LDO regulator 1001, similar to the aforementioned SCVD, may generate one or more voltages, based on the power supplied from an external power source (or from a DC/DC converter in case of the SIDO configuration in FIG. 8) and an external signal that controls the generation of different voltage levels. The signal for supplying power to the LDO 1001 and the external signal for controlling the generation of different voltage levels may be the same signal. As described above, in accordance with the external signal, the LDO regulator 1001 may generate a voltage (for example, V_PA) corresponding to each point in time according to the envelope signal, and may transmit, to the power amplifier, the current for supplying the voltage.

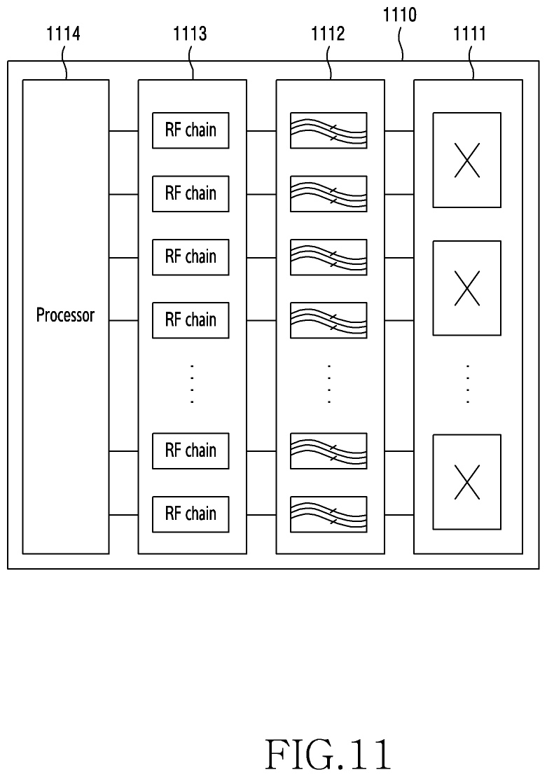

FIG. 11 illustrates the functional configuration of an electronic device including a power amplifier coupled with an AC-coupling supply modulator according to various embodiments of the disclosure. The electronic device 1110 may be included in one of the base station 110 or UE 120, 130 of FIG. 1. According to an embodiment, the electronic device 1110 (e.g., a base station) may be antenna equipment of an RFIC that includes one or more RF chains of the base station 110. In addition to the circuit structure of the supply modulator mentioned in FIGS. 1 to 10, an electronic device including the supply modulator is also included in the embodiments of the disclosure. The electronic device 1101 may include, as an RF component, a supply modulator including the power amplifier and converters mentioned in FIGS. 1 to 10.

Referring to FIG. 11, an exemplary functional structure of the electronic device 1110 is illustrated. The electronic device 1110 may include an antenna unit 1111, a filter unit 1112, a radio frequency (RF) processor 1113, and/or a controller 1114.

The antenna unit 1111 may include multiple antennas. The antennas perform functions for transmitting or receiving a signal through a radio channel. The antennas may each include a radiator including a substrate (e.g., a printed circuit board (PCB)) and a conductor or a conductive pattern formed thereon. The antennas may radiate an up-converted signal through a radio channel or obtain a signal radiated by another device. Each of the antennas may be referred to as an antenna element or an antenna device. In some embodiments, the antenna unit 1111 may include an antenna array having an array of multiple antenna elements. The antenna unit 1111 may be electrically connected to the filter unit 1112 through RF signal lines. The antenna unit 1111 may be mounted on a PCB including multiple antenna elements. The PCB may include multiple RF signal lines which connect antenna elements to filters of the filter unit 1112, respectively. These RF signal lines may be referred to as a feeding network. The antenna unit 1111 may provide a received signal to the filter unit 1112 or may radiate a signal provided from the filter unit 1112 into the air.

The filter unit 1112 may perform filtering in order to transmit a signal at a desired frequency. The filter unit 1112 may perform a function for selectively identifying a frequency by forming a resonance. The filter unit 1112 may include at least one of a band pass filter, a low pass filter, a high pass filter, or a band reject filter. That is, the filter unit 1112 may include RF circuits for obtaining a signal in a frequency band for transmission or a frequency band for reception. The filter unit 1112 according to various embodiments may electrically connect the antenna unit 1111 to the RF processor 1113.

The RF processor 1113 may include multiple RF paths. An RF path may be the unit of a path through which a signal received through an antenna or a signal radiated through an antenna passes. At least one RF path may be referred to as an RF chain. The RF chain may include multiple RF elements. The RF elements may include an amplifier, a mixer, an oscillator, a DAC, an ADC, and the like. For example, the RF processor 1113 may include an up-converter that upconverts a digital transmission signal in a baseband into a transmission frequency, and a digital-to-analog converter (DAC) that converts an up-converted digital transmission signal into an analog RF transmission signal. The up-converter and the DAC form a part of a transmission path. The transmission path may further include a power amplifier (PA) or a coupler (or combiner). In addition, for example, the RF processor 1113 may include an analog-to-digital converter (ADC) that converts an analog RF reception signal into a digital reception signal and a down-converter that converts a digital reception signal into a digital reception signal in a baseband. The ADC and the down-converter form a part of a reception path. The reception path may further include a low-noise amplifier (LNA) or a coupler (or divider). The RF components of the RF processor may be implemented on a PCB. The base station 1110 may have a structure in which the antenna unit 1111, the filter unit 1120, and the RF processor 1113 are stacked in sequence. The antennas and the RF components of the RF processor may be implemented on a PCB, and filters are repetitively coupled to each other between PCBs to form a plurality of layers.

The RF processor 1113 according to various embodiments may include multiple RF processing chains for paths of signals transferred to the antenna unit 1111 and the filter unit 1112. An RFIC may include the multiple RF processing chains. A signal applied in a baseband is input to the RFIC. The signal input to the RFIC is distributed to the respective antenna elements. For beamforming, independent phase shift may be each of the antenna elements. Accordingly, the RFIC may include RF processing chains for processing a signal to be transferred to each of the antenna elements. Each of the RF processing chains may include one or more RF components for RF signal processing. The RF processor 1113 may include a power modulator which can provide a modulated signal to a power amplifier on each RF path according to embodiments of the disclosure. The power modulator may include a DC-DC converter for providing DC power, a power generator connected in parallel to the DC-DC converter to provide transient current, and an AC-coupled capacitor.

The controller 1114 may control the overall operation of the electronic device 1110. The controller 1114 may include various modules for performing communication. The controller 1114 may include at least one processor such as a modem. The controller 1114 may control operations so that the respective units or elements according to various circuit architectures perform the functions according to various embodiments of the disclosure. The controller 1114 may include modules for digital signal processing. For example, the controller 1114 may include a modem. During data transmission, the controller 1114 generates complex symbols by encoding and modulating a transmitted bitstring. In addition, for example, during data reception, the controller 1114 restores a received bitstring through demodulation and decoding of a baseband signal. The controller 1114 may function as a protocol stack identified by communication standards.

In FIG. 11, the functional configuration of the electronic device 1110 is described as an example of equipment in which the supply modulator and power amplifier of the disclosure may be utilized. However, the example shown in FIG. 11 is merely an exemplary configuration for utilizing the antenna structure according to various embodiments of the disclosure described with reference to FIGS. 1 to 10, and the embodiments of the disclosure are not limited to the components of the equipment illustrated in FIG. 11. Accordingly, an RF module including a power amplifier including an impedance matching circuit, an RFIC, communication equipment with other configurations, and even the structure itself for the power amplifier may also be understood as embodiments of the disclosure.

In the disclosure, in order to describe a power amplifier filter and an electronic device including the same, a base station or a base station equipment (e.g., a radio unit (RU) or an access unit (AU)) for delivering signals in the mmWave band (or including a FR1/FR3 band) is described as an example, but the embodiments of the disclosure are not limited thereto. Wireless equipment performing functions equivalent to those of a base station, wireless equipment (e.g., TRP) connected to a base station, a terminal 120, or other communication equipment used for 5G communication are all applicable as a power amplifier and an electronic device including the same according to embodiments of the disclosure. Furthermore, although an antenna array has been described as an example of the structure of a plurality of antennas for communication in a multiple input multiple output (MIMO) environment, easy modification for beamforming is possible in some embodiments.

It should be noted that the above-described configuration diagrams, illustrative diagrams of control/data signal transmission methods, illustrative diagrams of operation procedures, and structural diagrams are not intended to limit the scope of the disclosure. That is, all constituent elements, entities, or operation steps described in the embodiments of the disclosure should not be construed as being essential for the implementation of the disclosure, and the disclosure may be implemented without impairing the essential features of the disclosure by including only some constituent elements. Also, the above respective embodiments may be employed in combination, as necessary. For example, the methods provided in the disclosure may be partially combined with each other to operate a network entity and a terminal.

The above-described operations of a base station or terminal or electronic device may be implemented by providing any unit of the base station or terminal device with a memory device storing the corresponding program codes. That is, a controller of the base station or terminal device may perform the above-described operations by reading and executing the program codes stored in the memory device by means of a processor or central processing unit (CPU).

Various units or modules of an entity, a base station device, or a terminal device may be operated using hardware circuits such as complementary metal oxide semiconductor-based logic circuits, firmware, or hardware circuits such as combinations of software and/or hardware and firmware and/or software embedded in a machine-readable medium. For example, various electrical structures and methods may be implemented using transistors, logic gates, and electrical circuits such as application-specific integrated circuits.

When the methods are implemented by software, a computer-readable storage medium for storing one or more programs (software modules) may be provided. The one or more programs stored in the computer-readable storage medium may be configured for execution by one or more processors within the electronic device. The at least one program includes instructions that cause the electronic device to perform the methods according to various embodiments of the disclosure as defined by the appended claims and/or disclosed herein.

These programs (software modules or software) may be stored in non-volatile memories including a random access memory and a flash memory, a read only memory (ROM), an electrically erasable programmable read only memory (EEPROM), a magnetic disc storage device, a compact disc-ROM (CD-ROM), digital versatile discs (DVDs), or other type optical storage devices, or a magnetic cassette. Alternatively, any combination of some or all of them may form a memory in which the program is stored. In addition, a plurality of such memories may be included in the electronic device.

Furthermore, the programs may be stored in an attachable storage device which can access the electronic device through communication networks such as the Internet, Intranet, local area network (LAN), wide LAN (WLAN), and storage area network (SAN) or a combination thereof. Such a storage device may access the electronic device via an external port. Also, a separate storage device on the communication network may access a portable electronic device.

In the above-described detailed embodiments of the disclosure, an element included in the disclosure is expressed in the singular or the plural according to presented detailed embodiments. However, the singular form or plural form is selected appropriately to the presented situation for the convenience of description, and the disclosure is not limited by elements expressed in the singular or the plural. Therefore, either an element expressed in the plural may also include a single element or an element expressed in the singular may also include multiple elements.

Although specific embodiments have been described in the detailed description of the disclosure, it will be apparent that various modifications and changes may be made thereto without departing from the scope of the disclosure. Therefore, the scope of the disclosure should not be defined as being limited to the embodiments set forth herein, but should be defined by the appended claims and equivalents thereof. That is, it will be apparent to those skilled in the art that other variants based on the technical idea of the disclosure may be implemented. Also, the above respective embodiments may be employed in combination, as necessary. As an example, the methods provided in the disclosure may be partially combined with each other to operate a base station and a terminal. Moreover, although the above embodiments have been described based on 5G and NR systems, other variants based on the technical idea of the embodiments may also be implemented in other communication systems such as LTE, LTE-A, and LTE-A-Pro systems.

Although specific embodiments have been described in the detailed description of the disclosure, it will be apparent that various modifications and changes may be made thereto without departing from the scope of the disclosure. Therefore, the scope of the disclosure should not be defined as being limited to the embodiments set forth herein, but should be defined by the appended claims and equivalents thereof.

Although the present disclosure has been described with various embodiments, various changes and modifications may be suggested to one skilled in the art. It is intended that the present disclosure encompass such changes and modifications as fall within the scope of the appended claims.

What is claimed is:

1. A supply modulator in a wireless communication system, the supply modulator comprising:
a voltage modulator configured to transmit, to a power amplifier, a first current for voltage switching;
a capacitor configured to maintain a voltage offset;
a controller configured to transmit a signal for controlling a voltage across both terminals of the capacitor; and
a direct current (DC)/DC converter configured to transmit, to the power amplifier, a second current for a supply modulation.

2. The supply modulator of claim 1, wherein the DC/DC converter and the power amplifier are connected by a first node,
wherein the DC/DC converter and the capacitor are connected by a second node,
wherein the capacitor and the voltage modulator are connected by a third node, and
wherein the DC/DC converter connected to the controller is arranged in parallel to the voltage modulator.

3. The supply modulator of claim 2, wherein the DC/DC converter transmits, to the power amplifier via the first node, the second current for the supply modulation,
wherein the DC/DC converter transmits, to the second node via the first node, a third current for controlling a voltage across both terminals of the capacitor, and
wherein the voltage modulator transmits, to the power amplifier via the third node, the first current for the voltage switching.

4. The supply modulator of claim 3, wherein the second node and the third node are connected by a summing node, and
wherein the signal for controlling a voltage across both terminals of the capacitor is generated based on the summing node.

5. The supply modulator of claim 3, wherein the voltage across both terminals of the capacitor is controlled to be equally maintained by the third current controlled by the controller, and
wherein the capacitor operates as an open element.

6. The supply modulator of claim 1, wherein the voltage modulator comprises:
a capacitor bank configured to generate one or more voltages; and
a voltage switch configured to determine a voltage for the voltage switching, and
wherein the voltage for the voltage switching is determined among the one or more voltages based on a control signal according to an envelope signal.

7. The supply modulator of claim 1, wherein the DC/DC converter comprises:
a pulse width modulation (PWM) control block configured to control PWM; and
a dead time block connected to the PWM control block and configured to control a dead time.

8. The supply modulator of claim 1, wherein the DC/DC converter and the power amplifier are connected by a switch node,
wherein the switch node and the voltage modulator are connected by a power node, and
wherein the power node is connected to the controller.

9. The supply modulator of claim 1, wherein the voltage modulator comprises:
a voltage generator configured to generate one or more voltages; and
a voltage switch configured to determine a voltage for the voltage switching,
wherein the voltage generator comprises one or more low-dropout (LDO) regulators configured to generate the one or more voltages, respectively, and
wherein the voltage for the voltage switching is determined among the one or more voltages based on a control signal according to an envelope signal.

10. The supply modulator of claim 1, wherein the voltage modulator comprises a low-dropout (LDO) regulator configured to generate a voltage for the voltage switching, and
wherein the voltage for the voltage switching is generated by a reference voltage control signal transmitted to the LDO regulator.

11. A radio frequency integrated circuit (RFIC) in a wireless communication system, the RFIC comprising:
a plurality of radio frequency (RF) processing chains,
wherein each of the plurality of RF processing chains comprises a supply modulator and a power amplifier, and
wherein the supply modulator comprises:
a voltage modulator configured to transmit, to the power amplifier, a first current for voltage switching;
a capacitor configured to maintain a voltage offset;
a controller configured to transmit a signal for controlling a voltage across both terminals of the capacitor; and
a direct current (DC)/DC converter configured to transmit, to the power amplifier, a second current for a supply modulation.

12. The RFIC of claim 11, wherein the DC/DC converter and the power amplifier are connected by a first node,
wherein the DC/DC converter and the capacitor are connected by a second node,
wherein the capacitor and the voltage modulator are connected by a third node, and
wherein the DC/DC converter connected to the controller is arranged in parallel to the voltage modulator.

13. The RFIC of claim 12, wherein the DC/DC converter transmits, to the power amplifier via the first node, the second current for the supply modulation,
wherein the DC/DC converter transmits, to the second node via the first node, a third current for controlling a voltage across both terminals of the capacitor, and
wherein the voltage modulator transmits, to the power amplifier via the third node, the first current for the voltage switching.

14. The RFIC of claim 13, wherein the second node and the third node are connected by a summing node, and
wherein the signal for controlling a voltage across both terminals of the capacitor is generated based on the summing node.

15. The RFIC of claim 13, wherein the voltage across both terminals of the capacitor is controlled to be equally maintained by the third current controlled by the controller, and
wherein the capacitor operates as an open element.

16. The RFIC of claim 11, wherein the voltage modulator comprises:
a capacitor bank configured to generate one or more voltages; and
a voltage switch configured to determine a voltage for the voltage switching, and
wherein the voltage for the voltage switching is determined among the one or more voltages, based on a control signal according to an envelope signal.

17. The RFIC of claim 11, wherein the DC/DC converter comprises:
a pulse width modulation (PWM) control block configured to control PWM; and
a dead time block connected to the PWM control block and configured to control a dead time.

18. The RFIC of claim 11, wherein the DC/DC converter and the power amplifier are connected by a switch node,
wherein the switch node and the voltage modulator are connected by a power node, and
wherein the power node is connected to the controller.

19. The RFIC of claim 11, wherein the voltage modulator comprises:
a voltage generator configured to generate one or more voltages; and
a voltage switch configured to determine a voltage for the voltage switching,
wherein the voltage generator comprises one or more low-dropout (LDO) regulators configured to generate the one or more voltages, respectively, and
wherein the voltage for the voltage switching is determined among the one or more voltages, based on a control signal according to an envelope signal.

20. The RFIC of claim 11, wherein the voltage modulator comprises a low-dropout (LDO) regulator configured to generate a voltage for the voltage switching, and
wherein the voltage for the voltage switching is generated by a reference voltage control signal transmitted to the LDO regulator.
